(19) United States
(12) Patent Application Publication
(10) Pub. No.: US 2026/0130122 A1
(43) Pub. Date: May 7, 2026

(54) WINDOW FABRICATION PROCESS FOR SUPERCONDUCTING QUBIT JUNCTIONS AND CROSSOVERS

(71) Applicant: Qolab, Inc., Los Angeles, CA (US)

(72) Inventors: John Matthew Martinis, Santa Barbara, CA (US); Robert Francis McDermott, III, Madison, WI (US); Alan Kar-Lun Ho, Los Angeles, CA (US)

(21) Appl. No.: 18/935,215

(22) Filed: Nov. 1, 2024

(51) Int. Cl. H10N 60/01; H10N 60/12; H10N 60/80; H10N 60/85

(52) U.S. Cl. CPC H10N 60/0912; H10N 60/12; H10N 60/805; H10N 60/85

(57) ABSTRACT

Described herein is a fabrication process for creating quantum devices including superconducting qubits, specifically Josephson tunnel junctions and crossovers. The process includes depositing and patterning a first metal layer on a qubit substrate to form the base structure of the circuit. A scaffolding layer is then applied, subsequently patterned and etched to create windows revealing the metal layer below. A thin insulating barrier is introduced within the window followed by the deposition of a second metal layer. This layered structure within the window forms a Josephson junction for the quantum bit. A second larger window serves to connect the Josephson junction to other devices within the circuit. The scaffolding layer is finally removed, creating an air gap in the circuit to isolate the first and second metal layers.

### BACKGROUND

### Field of Disclosure

This invention relates generally to quantum computing, and more particularly to the fabrication of superconducting qubits for greater coherence and reliability.

### Description of Related Art

Quantum computers perform calculations that cannot be run by classical supercomputers, such as efficient prime factorization or solving how molecules bind using quantum chemistry. Quantum computers can be made from a variety of physical systems such as superconducting qubits, trapped ion systems, photonic systems, etc.

An advantage of superconducting qubits is that they can be fabricated using standard integrated-circuit technology, enabling scaling of the number of qubits to large size similar to their conventional electronics counterparts. Although superconducting qubits use thin-film deposition and etch equipment that is common to typical fabrication processing like CMOS, special processes are necessary for good qubit performance. In particular, dielectrics like amorphous silicon dioxide have large energy loss at low temperature and are generally not compatible with quantum computing devices.

This identified deficiency is important because a critical component called the Josephson tunnel junction, which gives a non-linear inductance crucial for producing useful quantum states, is typically fabricated with a lift-off process. Lift off processes oftentimes leave residue and rough edges that can degrade qubit coherence. In some fabrication processes, a lift-off process is not used, but instead the process employs a second crossed metal wire for the junction. However, this process requires a cleaning step that produces amorphous silicon underneath this electrode, which introduces additional energy loss.

Accordingly, a fabrication process for Josephson junction superconducting qubits that avoids traditional lift-off processes would be beneficial.

### SUMMARY

A technique to create a quantum computing device using lithographic processes is described. In particular, the Specification and Drawings describe a process to create Josephson junctions and crossover wiring contacts that uses standard processing steps of deposition and etch. The selected processing steps are reliable and are demonstrated in conventional CMOS electronics for devices with billions of transistors. The described device and fabrication process are superior to devices and methods employing present-day lift-off processes, which show qubit dropouts even at the scale of 50-100 qubits. For the described process, etching the metal gives clean edges instead of a diffuse edge with many small metal islands that are produced during a lift-off process. The etching process described herein lessens the number of surface defects such as, e.g., the two-level states that degrade coherence relative to the traditional number of surface defects generated by the lift-off process.

In addition, the Josephson junction area is defined by a window etched into a sacrificial layer of silicon dioxide. The etching process to create the window is conducted using the same process step to create vias in standard CMOS processing. Since vias are a critical process step in complex integrated-circuit processing, the parameters for via etch are well known and thus the window area can be controlled reliably. This enables better control of the Josephson junction critical current, a key parameter for making qubits with the correct transition frequency.

During fabrication of the quantum device, silicon dioxide acts as a scaffold for the Josephson junction and crossovers, and is removed before using the device (because, if it remained, the material would cause a large loss in the device). Silicon dioxide is chosen because it can be etched with vapor HF, which does not collapse the resulting bridge structure since it etches in a vapor phase without liquid surface tension.

### BRIEF DESCRIPTION OF DRAWINGS

FIG. 1 shows a cross-section view of a quantum device fabricated using the disclosed process, according to an example embodiment.

FIG. 2 shows a cross-section view of a quantum device fabricated using the disclosed process and including a crossover electrode, according to an example embodiment.

FIG. 3 illustrates a workflow diagram for fabricating a circuit comprising superconducting quantum bits, according to an example embodiment.

The figures depict various embodiments for purposes of illustration only. One skilled in the art will readily recognize from the following discussion that alternative embodiments of the structures and methods illustrated herein may be employed without departing from the principles described herein.

### DETAILED DESCRIPTION

As described above, fabricating quantum devices such as, e.g., a Josephson tunnel junction for a superconducting qubit without traditional lithography lift-off processes is beneficial because the resulting devices have better performance than those fabricated using lift-off processes.

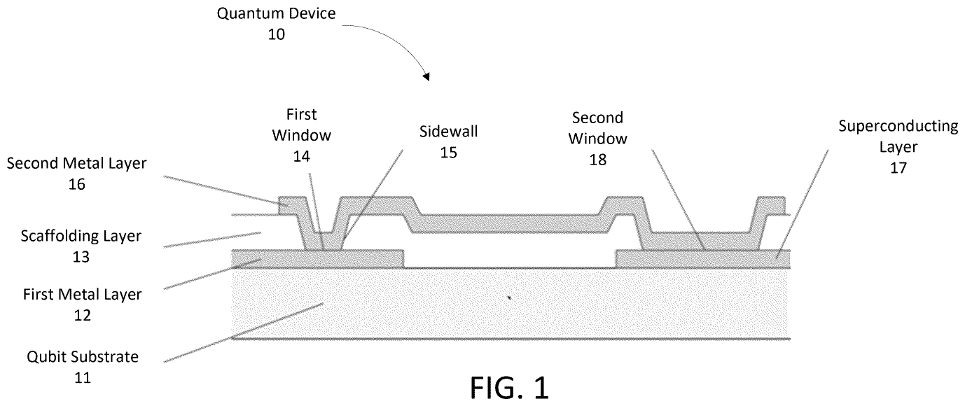

FIG. 1 shows a cross-section view of a quantum device fabricated using the disclosed process, according to an example embodiment. The illustrated quantum device 10 is a Josephson tunnel junction for a superconducting qubit.

The quantum device 10 has a qubit substrate 11. The qubit substrate 11 is typically silicon or sapphire but could be other materials. A first metal layer 12 is formed on a top surface of the qubit substrate 11. The first metal layer 12 is typically made from aluminum but could be made from other materials. The first metal layer 12 is deposited as a blanket film, typically by sputtering or some other process, and is then etched with a liquid or reactive ion etch with features defined by photolithography. The first metal layer 12 is typically 100 nm thick but can range from 30 nm to 300 nm thick.

A scaffolding layer 13 is deposited over the entire wafer (e.g., qubit substrate 11 and first metal layer 12). The scaffolding layer 13 is typically made from silicon dioxide but could be other materials. The scaffolding layer 13 is deposited such that it has a smooth conformal coating over the edges of the first metal layer 12. The thickness of the scaffolding layer 13 is typically 200 nm but can range from about 75% of the thickness of the first metal layer 12, to about 500 nm.

The scaffolding layer 13 is etched and then patterned to form windows 14. That is, the scaffolding layer 13 is processed to remove a portion of the scaffolding layer 13 and expose the underlying metallization layer (e.g., first metal layer 12) via a first window 14. The etching process may be a reactive ion etcher with fluorine chemistry, but other etching processes and chemistries are also possible. The patterning process may be either optical or electron-beam lithography, but other processes are also possible. In configurations where the fluorine chemistry is utilized for a silicon dioxide etch, the process will not chemically etch the underlying first metal layer 12.

The windows 14 have a typical feature size of 150 nm (e.g., diameter, length, width, etc.) but may have other sizes. The windows 14 may be circular or square shape but other shapes are possible. Window feature sizes (e.g., diameter, length, width, etc.) can range from 30 nm to 10 um in size but other sizes are also possible. The etching process may create windows having a tapered sidewall 15. The tapered sidewall 15 may have a 70 to 80 degree slope, but other slopes are possible. The tapered sidewall 15 aids in filling the windows 14 during the subsequent deposition of the second electrode layer (e.g., second metal layer 16).

Before deposition of the second metal layer 16, the windows 14 are cleaned to remove residues and/or residuals. For example, the windows 14 may be cleaned to remove the 2-4 nm aluminum oxide that was grown during previous processing steps. Cleaning may be accomplished with an ion mill or plasma etch using, e.g., an inert gas such as Argon, but other cleaning processes are also possible.

For producing a Josephson tunnel junction, a thin 1-3 nm insulating barrier is created in the first window 14. The insulating barrier is created by introducing oxygen gas which generates a thin oxide layer. The parameters of the oxygen gas for creating the insulating barrier are those known to ones skilled in the art and are typical for modern semiconductor manufacturing. In some configurations, the barrier can also be created using an oxygen plasma. In whatever configuration, the insulating barrier can be generated without breaking the vacuum. In general, higher pressure and longer oxygen exposure creates a higher resistance tunnel junction.

The tunnel barrier (present in the first window 14) is then capped with the second metal layer 16. The second metal layer 16 may be sputtered aluminum but could be other metals. The second metal layer 16 may be applied without breaking vacuum. The thickness of the second metal layer 16 is chosen to smoothly coat the sidewalls 15 of the first window 14 of the silicon dioxide scaffolding layer 13. The thickness may be 100 to 500 nm thick and could be other thicknesses. The second metal layer 16 is patterned and etched as for the first metal layer 12.

Accordingly, a Josephson junction is created in the first window 14. The Josephson junction is the area where the tunneling barrier is formed between the first metal layer 12 (e.g., a superconducting metal such as aluminum) and the second metal layer 16 (a superconducting metal such as aluminum). That is, the first window 14 includes a layered structure comprising the a tunneling junction between an area of the first metal layer 12 and the second metal layer 16.

An isolated Josephson junction is less useful than one connected to other devices and structures. To connect the Josephson junction in the first window 14 to a separate electrode in the superconducting base layer 17 (e.g., another metal layer), a second window 18 is fabricated at the same time as the first window 14. The second window 18 has a larger area than the first window 14 to act like a short, with an area typically 10-100 times larger than the first window 14 including the Josephson junction. The length of the second metal layer 16 between the first window 14 and the second window 18 is typically 1 to 20 um. This allows the free-standing metal bridge created after scaffolding layer 13 removal (described below) to be mechanically robust.

The silicon dioxide scaffolding layer 13 is removed from the quantum device to create an air gap within the circuit. The air gap separates the first metal layer 12 and the second metal layer 16 within the device. Generally, the air gap separates the first and second metal layers 12, 16 surrounding the area of the Josephson junction formed in the first window 14 and the short in the second window 18. The scaffolding layer 13 may be removed using a vapor hydrogen fluoride etch, which does not damage the resulting free-hanging structure from surface tension. Contrarily, a liquid etch (e.g., a lift-off process) would collapse the scaffolding layer 13 and there would be no free-hanging structure.

Generally, a high-quality silicon dioxide is used to form the scaffolding layer 13. High quality silicon dioxide is silicon dioxide with a high density as measured by the industry-standard wet etch rate ratio (WERR). This ratio represents the ratio of liquid HF acid etch rate of the sacrificial oxide to that of thermally grown silicon dioxide. High-quality sacrificial silicon dioxide will have WERR around 3 or lower and will leave minimal to no residues when removed by vapor HF etch. By contrast, the vapor HF etch of low-quality silicon dioxide leaves residues that produce qubit energy loss.

Typically, cleaning of the first metal layer 12 with the argon ion mill creates a thin 1-2 nm amorphous layer in the first metal layer 12 in the first window 14. The amorphous layer does not degrade the aluminum since it will be naturally amorphized when oxidized. The argon ion mill cleaning step also may damage the silicon dioxide scaffolding layer 13, but this is inconsequential because this scaffolding layer 13 is removed at the last vapor HF etch. The vacuum gap between the upper electrode (e.g., second metal layer 16) and lower electrode (e.g., first metal layer 12 and/or superconducting layer 17) also lowers the capacitance of the junction crossover lead, which helps to lower its contribution to qubit energy loss.

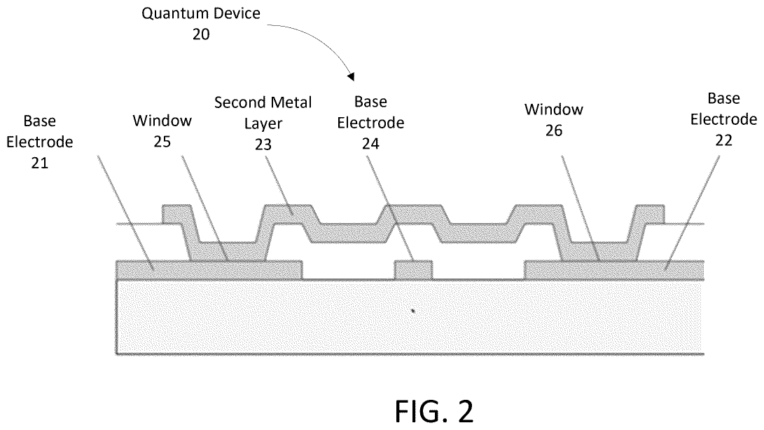

Quantum devices made with this process can also enable crossover wiring. FIG. 2 shows a cross-section view of a quantum device fabricated using the disclosed process and including a crossover, according to an example embodiment. Here, the quantum device 20 includes a base electrode 21 (e.g., the first metal layer) electrically connected to the base electrode 22 (e.g., superconducting layer 17) through the second metal layer 23 (e.g., second metal layer 16). The illustrated device also includes an additional base electrode 24 that is electrically isolated from the base electrode 21 and the base electrode 22. The windows 25 and 26 are made similarly for the Josephson junctions, except that the metal is not oxidized after cleaning. This forms a large critical current connection that acts like a short. Typical sizes for these crossover windows are 0.1 to 3 um in diameter.

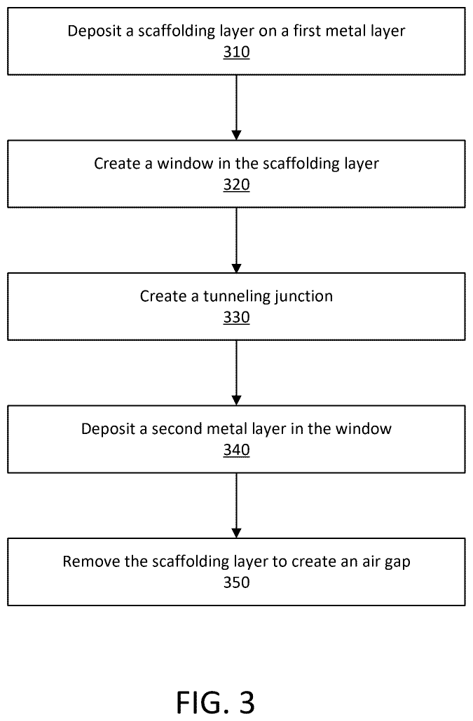

FIG. 3 illustrates a workflow diagram for fabricating a circuit comprising superconducting quantum bits, according to an example embodiment. The workflow 300 may include additional or fewer steps and/or the steps may be performed in a different order. Moreover, one or more of the steps may be repeated, or the entire workflow may be repeated.

Within the context of the workflow, the circuit is fabricated using semiconductor manufacturing machines and their corresponding processes (a “fabricator” for simplicity).

To create the circuit, the fabricator deposits a first metal layer on a qubit substrate. The fabricator deposits 310 a scaffolding layer on a first metal layer. The first metal layer is patterned to define at least a first portion of the circuit comprising a superconducting quantum bit.

The fabricator creates 320 a window in the scaffolding layer to provide access to the first metal layer by removing a volume of the scaffolding layer.

The fabricator creates 330 a tunneling junction for the superconducting quantum bit in the window of the scaffolding layer (e.g., by introducing an oxygen gas).

The fabricator deposits 340 a second metal layer in the window. The second metal layer is patterned to form at least a second portion of the circuit comprising the superconducting quantum bit. A layered structure of the first metal layer, the tunneling junction, and the second metal layer in the window of the scaffolding layer form a Josephson junction for the superconducting quantum bit of the circuit.

The fabricator removes 350 the scaffolding layer to create an air gap in the circuit between the first metal layer and the second metal layer outside of the Josephson junction.

In the description above, for purposes of explanation, numerous specific details are set forth in order to provide a thorough understanding of the illustrated system and its operations. It will be apparent, however, to one skilled in the art that the system may be operated without these specific details. In other instances, structures and devices are shown in block diagram form in order to avoid obscuring the system.

Reference in the specification to “one embodiment” or “an embodiment” means that a particular feature, structure, or characteristic described in connection with the embodiment is included in at least one embodiment of the system. The appearances of the phrase “in one embodiment” in various places in the specification are not necessarily all referring to the same embodiment.

Some portions of the detailed descriptions are presented in terms of algorithms or models and symbolic representations of operations on data bits within a computer memory. An algorithm is here, and generally, conceived to be steps leading to a desired result. The steps are those requiring physical transformations or manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the following discussion, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Some of the operations described herein are performed by a computer physically mounted within a machine. This computer may be specially constructed for the required purposes, or it may comprise a general-purpose computer selectively activated or reconfigured by a computer program stored in the computer. Such a computer program may be stored in a computer-readable storage medium, such as, but is not limited to, any type of disk including floppy disks, optical disks, CD-ROMs, and magnetic-optical disks, read-only memories (ROMs), random access memories (RAMs), EPROMs, EEPROMs, magnetic or optical cards, or any type of non-transitory computer-readable storage medium suitable for storing electronic instructions.

The figures and the description above relate to various embodiments by way of illustration only. It should be noted that from the following discussion, alternative embodiments of the structures and methods disclosed herein will be readily recognized as viable alternatives that may be employed without departing from the principles of what is claimed.

One or more embodiments have been described above, examples of which are illustrated in the accompanying figures. It is noted that wherever practicable similar or like reference numbers may be used in the figures and may indicate similar or like functionality. The figures depict embodiments of the disclosed system (or method) for purposes of illustration only. One skilled in the art will readily recognize from the following description that alternative embodiments of the structures and methods illustrated herein may be employed without departing from the principles described herein.

Some embodiments may be described using the expression “coupled” and “connected” along with their derivatives. It should be understood that these terms are not intended as synonyms for each other. For example, some embodiments may be described using the term “connected” to indicate that two or more elements are in direct physical or electrical contact with each other. In another example, some embodiments may be described using the term “coupled” to indicate that two or more elements are in direct physical or electrical contact. The term “coupled,” however, may also mean that two or more elements are not in direct physical or electrical contact with each other, but yet still co-operate or interact with each other. The embodiments are not limited in this context.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present), and B is false (or not present), A is false (or not present), and B is true (or present), and both A and B is true (or present).

In addition, the use of the “a” or “an” are employed to describe elements and components of the embodiments herein. This is done merely for convenience and to give a general sense of the system. This description should be read to include one or at least one and the singular also includes the plural unless it is obvious that it is meant otherwise.

Upon reading this disclosure, those of skill in the art will appreciate still additional alternative structural and functional designs for a system and a process for implementing the functionality described herein. Thus, while particular embodiments and applications have been illustrated and described, it is to be understood that the disclosed embodiments are not limited to the precise construction and components disclosed herein. Various modifications, changes, and variations, which will be apparent to those, skilled in the art, may be made in the arrangement, operation, and details of the method and apparatus disclosed herein without departing from the spirit and scope defined in the appended claims.

What is claimed is:

1. A method for fabricating a circuit comprising superconducting quantum bits, the method comprising:
depositing a scaffolding layer on a first metal layer, the first metal layer patterned to define at least a first portion of the circuit comprising a superconducting quantum bit;
creating a window in the scaffolding layer to provide access to the first metal layer by removing a volume of the scaffolding layer;
creating a tunneling junction for the superconducting quantum bit in the window of the scaffolding layer;
depositing a second metal layer in the window, wherein the second metal layer is patterned to form at least a second portion of the circuit comprising the superconducting quantum bit, and a layered structure of the first metal layer, the tunneling junction, and the second metal layer in the window of the scaffolding layer form a Josephson junction for the superconducting quantum bit of the circuit; and
removing the scaffolding layer to create an air gap in the circuit between the first metal layer and the second metal layer outside of the Josephson junction.

2. The method of claim 1, further comprising:
creating a third metal layer, the third metal layer patterned to form at least a third portion of the circuit, and
wherein the second metal layer and the third metal layer form a crossover, wherein the air gap extends between the second metal layer and the third metal layer such that the second metal layer is suspended over the third metal layer.

3. The method of claim 1, wherein the window has a first dimension less than 0.3 um and a second dimension orthogonal to the first dimension less 0.3 um.

4. The method of claim 1, wherein the first metal layer and the second metal layer comprise aluminum.

5. The method of claim 1, wherein the scaffolding layer comprises silicon dioxide and a thickness of the scaffolding layer is 0.05 to 1 um.

6. The method of claim 1, wherein removing an area of the scaffolding layer to create the window comprises performing fluorine-based reactive ion etching on the scaffolding layer.

7. The method of claim 1, further comprising, after creating the window in the scaffolding layer, cleaning the second metal layer using an ion mill or plasma in a vacuum.

8. The method of claim 7, wherein cleaning the second metal layer using the ion mill or plasma comprises using argon for the ion mill or plasma.

9. The method of claim 1 wherein creating the tunneling junction comprises depositing the second metal layer in the window without an oxidation step.

10. The method of claim 1, wherein the scaffolding layer comprises high-density silicon dioxide having a wet etch ratio for hydrofluoric acid less than 3.

11. The method of claim 1, wherein removing the scaffolding layer to create the air gap comprises etching the scaffolding layer using a hydrofluoric acid vapor.

12. The method of claim 1, wherein the window comprises a wall angle from 65 to 85 degrees.

13. A quantum circuit comprising:
a first metal layer patterned to form at least a first portion of the circuit;
a second metal layer patterned to form at least a second portion of the circuit; and
a superconducting quantum bit comprising:
a Josephson junction comprising a layered structure, the layered structure comprising an area of the first metal layer, a tunneling junction, and an area of the second metal layer; and
wherein the Josephson junction is formed in a window of a scaffolding layer deposited on the first metal layer; and
wherein an air gap is formed within the quantum circuit between the first metal layer and the second metal layer by removing the scaffolding layer outside of the Josephson junction.

14. The quantum circuit of claim 13, further comprising:
a third metal layer, the third metal layer patterned to form at least a third portion of the circuit, and
wherein the second metal layer and the third metal layer form a crossover, wherein the air gap extends between the second metal layer and the third metal layer such that the second metal layer is suspended over the third metal layer.

15. The quantum circuit of claim 13, wherein the window has a first dimension less than 0.3 um and a second dimension orthogonal to the first dimension less 0.3 um.

16. The quantum circuit of claim 13, wherein the first metal layer and the second metal layer comprise aluminum.

17. The quantum circuit of claim 13, wherein the scaffolding layer comprises high-density silicon dioxide having a wet etch ratio for hydrofluoric acid less than 3.

18. The quantum circuit of claim 13, wherein the window has a first dimension less than 0.3 um and a second dimension orthogonal to the first dimension less 0.3 um.

19. The method of claim 1, wherein the window comprises a wall angle from 65 to 85 degrees.
